(19) United States
(12) Patent Application Publication
(10) Pub. No.: US 2025/0329984 A1
(43) Pub. Date: Oct. 23, 2025

(54) TUNABLE LASER DIODE ASSEMBLY FOR HEAT DISSIPATION AND COLLIMATION

(71) Applicant: SeekOps Inc., Austin, TX (US)

(72) Inventors: Garrett Niall John, Escondido, CA (US); Brendan James Smith, Lakeway, TX (US)

(21) Appl. No.: 18/870,370

(22) PCT Filed: May 30, 2023
(86) PCT No.: PCT/US2023/023905

§ 371 Date: Nov. 27, 2024

Related U.S. Application Data
(60) Provisional application No. 63/347,476, filed on May 31, 2022.

(51) Int. Cl. H01S 5/024; H01S 5/00; H01S 5/02208

(52) U.S. Cl. CPC H01S 5/02415; H01S 5/005; H01S 5/02208

(57) ABSTRACT

Systems, devices, and methods for a laser diode assembly including: a laser diode configured to emit a laser beam; and a housing configured to receive at least a portion of the laser diode, where the housing includes: a first cylindrical portion defining a first chamber, where the laser diode is at least partially disposed in the first chamber; and a flange structure connected to the first cylindrical portion, where the flange structure comprises a base extending radially outwardly from the first cylindrical portion and a plurality of fins arranged linearly along the base and extending outwardly from the base, where the plurality of fins facilitates in dissipating a heat generated by the laser diode.

### CROSS-REFERENCE TO RELATED APPLICATIONS

This application is a 35 U.S.C § 371 National Stage Entry of International Application No. PCT/US23/23905, filed May 30, 2023, which claims the priority benefit of U.S. Provisional Patent Application Ser. No. 63/347,476 filed May 31, 2022, all of which are hereby incorporated herein by reference in their entirety for all purposes.

### FIELD OF ENDEAVOR

The invention relates to a laser diode assembly, and more particularly to heat sinks for dissipating heat from a laser diode assembly.

### BACKGROUND

Laser manufacturers are continuously developing low-noise, narrow-linewidth, and precise wavelength tunable laser diode systems. The benefit of utilizing a tunable diode laser is that the material properties of the emitter (diode) substrate allow for the ability to precisely tune the laser wavelength to less than one nanometer or narrower. However, precise control over the current and temperature of the emitter is required to control the wavelength of light emitted. These tunable laser diode systems can therefore have significant waste heat generated by the laser systems or may require heating to regulate diode temperature. Active liquid cooling systems use fluid systems having mechanical pumps and coolants to dissipate the heat generated by the laser systems and are thus bulky and heavy. Temperature control for laser systems is typically a single function and requires separate sub-assemblies for collimation or electronic interface/drive.

### SUMMARY

A system embodiment may include a tunable laser diode assembly having a laser diode adapted to emit a controllable wavelength of light and housing for support, and at least partially, the laser diode. The housing includes a first cylindrical portion defining a first chamber, or cavity, housing the laser diode, and a flange structure connected to the first cylindrical portion. The flange structure has a base extending radially outwardly of the first cylindrical portion and a plurality of fins arrayed linearly along the base and extending outwardly from the base. The plurality of fins facilitates in dissipating heat generated by the laser diode. The flange structure may further have a second cylindrical portion extending axially from the first cylindrical portion that houses a collimating optic to generate a laser beam.

A method embodiment may include a step for mounting a support flange and a circuit board to a mounting flange of a laser diode, a step for monitoring the temperature of a laser diode, a step for determining whether the temperature of the laser diode has met a predetermined setpoint and a step for cooling the laser diode so that the temperature of the laser diode is below the predetermined setpoint.

Another method embodiment may include a step for mounting a support flange and a circuit board to a mounting flange of a laser diode, a step for monitoring the temperature of a laser diode, a step for determining whether the temperature of the laser diode has met a predetermined setpoint and a step for cooling the laser diode so that the temperature of the laser diode is below the predetermined setpoint.

A system embodiment may comprise a laser assembly comprising a laser diode, collimated optics and a multi-pass cell configured to adapt and emit a laser beam within the laser assembly. The laser diode assembly is mounted on the multi-pass cell. A laser diode assembly comprises a first cylindrical portion comprising the laser diode; and a second cylindrical portion comprising the collimated optics. In one embodiment, the multi-pass cell is a multi-pass cell comprising a first mirror, a second mirror and threads. The collimated optics is coupled to the multi-pass cell via external threads and threads. In a second embodiment, the multi-pass cell is a multi-pass cell comprising a first mirror, a second mirror and a receiving feature (cavity). For this second embodiment, the collimated optics are coupled to the multi-pass cell via extruded feature (core) and receiving feature (cavity). In a third embodiment, the multi-pass cell is a dual-pass cell comprising one mirror and threads. In a fourth embodiment, the multi-pass cell is a single pass cell and does not comprise any mirrors.

### BRIEF DESCRIPTION OF THE DRAWINGS

The components in the figures are not necessarily to scale, emphasis instead being placed upon illustrating the principals of the invention. Like reference numerals designate corresponding parts throughout the different views. Embodiments are illustrated by way of example and not limitation in the figures of the accompanying drawings, in which:

FIG. 1 depicts a perspective view of a laser assembly having a laser diode assembly, according to one embodiment;

FIG. 2 depicts a front perspective view of the laser diode assembly of FIG. 1;

FIG. 3 depicts a rear perspective view of the laser diode assembly of FIG. 1;

FIG. 4 depicts a front perspective exploded view of the laser diode assembly, according to one embodiment;

FIG. 5 depicts a rear perspective exploded view of the laser diode assembly, according to one embodiment;

FIG. 6 depicts a rear perspective view of a housing of the laser diode assembly, according to one embodiment;

FIG. 7 depicts a front perspective view of a housing of the laser diode assembly, according to one embodiment;

FIG. 8 depicts a portion of the laser assembly having a circuit board operatively connected with a laser diode of the laser diode assembly, according to one embodiment;

FIG. 9 is a flow chart depicting a method embodiment for cooling a laser diode, according to one embodiment;

FIG. 10A is a high-level block diagram of a laser diode assembly, according to one embodiment;

FIG. 10B is a high-level block diagram of a laser diode assembly, according to another embodiment;

FIG. 10C is a high-level block diagram of a laser diode assembly, according to another embodiment;

FIG. 10D is a high-level block diagram of a laser diode assembly, according to another embodiment;

FIG. 11 is a temperature control block diagram using a computer, with a single stage, according to one embodiment;

FIG. 12 is a temperature control block diagram using a computer, with three stages, according to another embodiment;

FIG. 13 is a temperature control block diagram using a computer, with N stages, according to another embodiment.

FIG. 14 is a temperature control block diagram using a PID loop, according to one embodiment;

FIG. 15 is a tunable diode laser control, according to one embodiment;

FIG. 16 is a laser diode assembly with an integrated Peltier Thermoelectric Cooler, according to one embodiment;

FIG. 17 is a laser diode assembly with an integrated Peltier Thermoelectric Cooler, according to a second embodiment;

FIG. 18 is a laser diode assembly with an integrated Peltier Thermoelectric Cooler, according to a third embodiment;

FIG. 19 is a laser diode assembly with an integrated Peltier Thermoelectric Cooler, according to a fourth embodiment; and

FIG. 20 depicts a collimating optic distance from an emission source, according to one embodiment.

### DETAILED DESCRIPTION

The following description is made for the purpose of illustrating the general principles of the embodiments discloses herein and is not meant to limit the concepts disclosed herein. Further, particular features described herein can be used in combination with other described features in each of the various possible combinations and permutations. Unless otherwise specifically defined herein, all terms are to be given their broadest possible interpretation including meanings implied from the description as well as meanings understood by those skilled in the art and/or as defined in dictionaries, treatises, etc.

The present system allows for a small, lightweight heatsink for a laser diode assembly operating below 100° C. The disclosed heat sink also provides mounting points for a small DC fan and may be used to house a collimating optic for the laser diode assembly. The present system allows for a small, lightweight heatsink for a laser diode assembly operating in environments above −50° C. and below 100° C. and laser diodes emitting less than 50 mW of output power and lasing at temperatures above 0° C. and below 50° C. The disclosed heat sink also provides mounting points for a small electronic fan and may be used to house a collimating optic for the laser diode assembly. One objective is to control the temperature of the laser diode to within 0.1° C. of the desired setpoint. This type of assembly allows for the precise placement of the collimating optic at the working distance. Additionally, this assembly allows for axial adjustment of the collimating optic with respect to the emitter source and allows for the tuning of the beam profile and/or adjustment of the beam profile.

In some embodiments, “collimation” may refer to all the optical elements in an instrument being on their designed optical axis. It may also refer to the process of adjusting an optical instrument so that all its elements are on that designed axis (in line and parallel). In optics, a collimator may include a curved mirror or lens with some type of light source and/or an image at its focus.

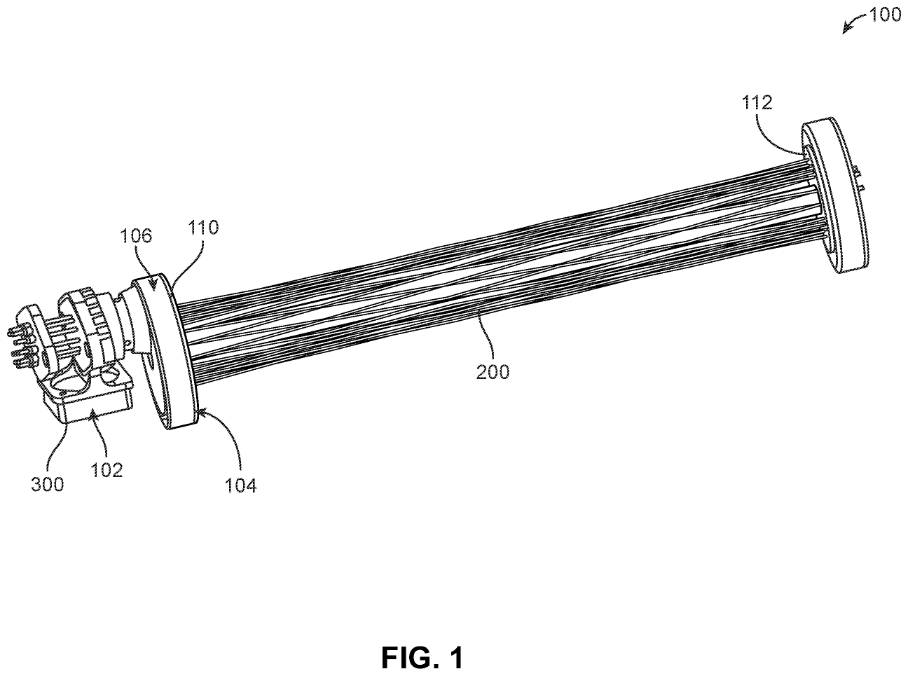

Referring to FIG. 1, a laser assembly 100 having a laser diode assembly 102 mounted on a multi-pass cell 104, for example, a Herriott cell 106, is shown. The multi-pass cell 104 may include one or more mirrors, for example, a first mirror 110 and a second mirror 112. The first mirror 110 may be arranged spaced apart and opposite from the second mirror 112. The first mirror 110 may be located at a predetermined distance from the second mirror 112. The laser diode assembly 102 may be coupled to the multi-pass cell 104 proximate the first mirror 110. The laser diode assembly 102 may be adapted to emit a laser beam 200. The laser beam 200 may enter inside the multi-pass cell 104 through an opening in the first mirror 110, reflect multiple time inside the multi-pass cell 104 between the first mirror 110 and the second mirror 112 over a path length, and exit the multi-pass cell 104 through an opening in the second mirror 112.

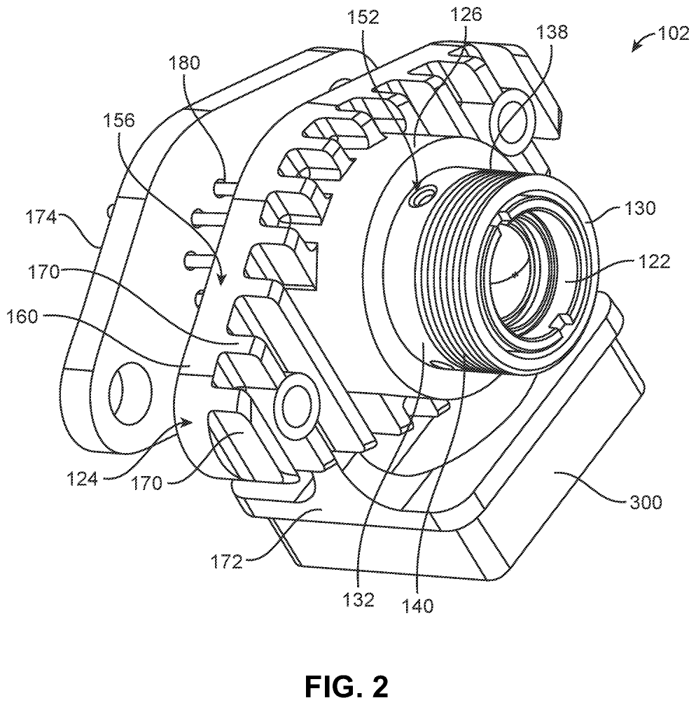

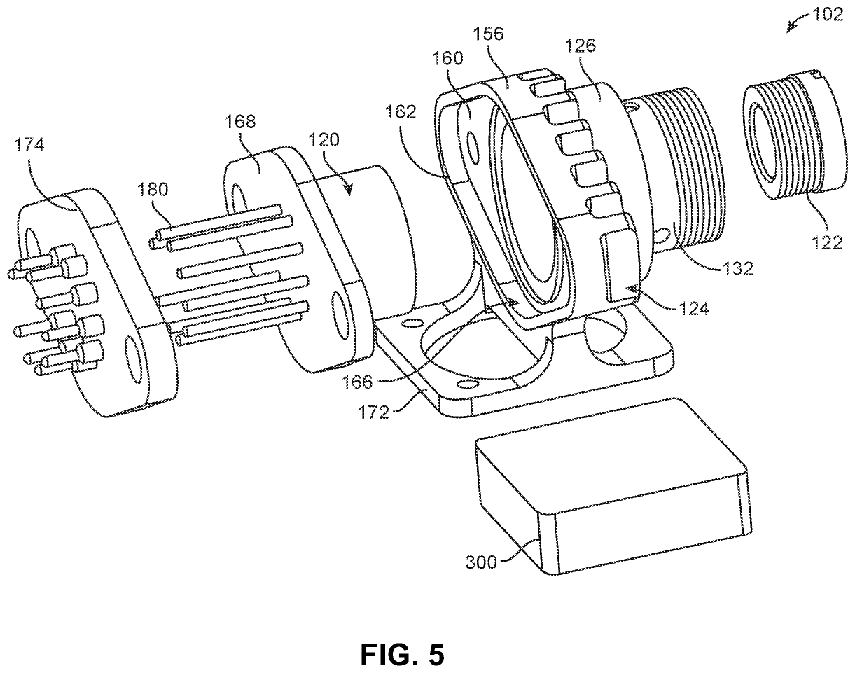

Referring to FIGS. 2-7, the laser diode assembly 102 includes a laser diode 120 adapted to emit a laser beam (200, FIG. 1), collimated optics 122 or lens, and a housing 124 adapted to support the laser diode 120 and the collimated optics 122. The housing 124 may facilitate a mounting of the laser diode assembly 102 onto the multi-pass cell (104, FIG. 1). The laser diode (120) may be coupled to collimated optics (122), which in turn may be coupled to a multi-pass cell (104). Embodiments described herein assume a cylindrical structure to house the components in for laser diode assembly 102. However, other structures may support the functionalities discussed relative to a tunable laser diode assembly having a laser diode adapted to emit a controllable wavelength of light.

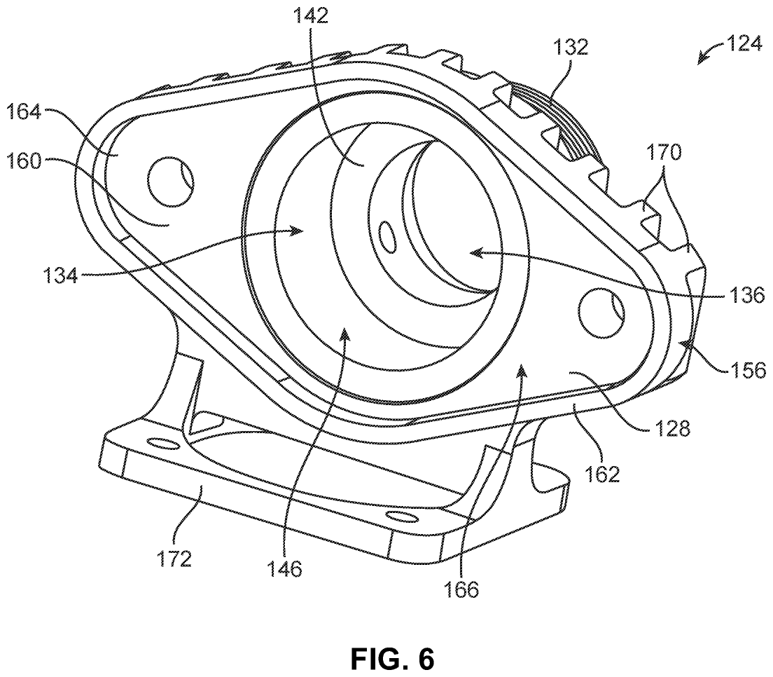

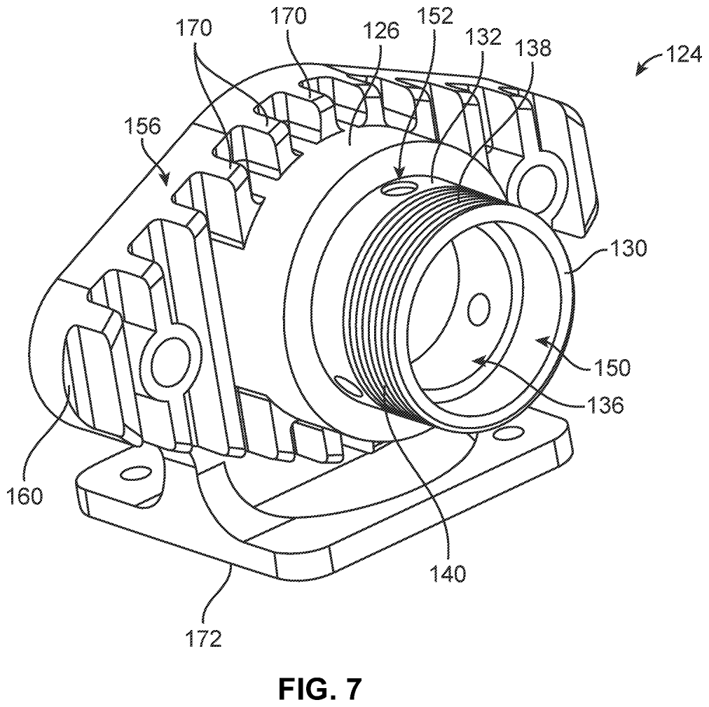

The housing 124 includes a first cylindrical portion 126 extending from a first longitudinal end 128 towards a second longitudinal end 130 of the housing 124, and a second cylindrical portion 132 extending from the first cylindrical portion 126 towards the second longitudinal end 130. The first cylindrical portion 126 defines a first chamber 134 (See FIG. 6) to receive at least a portion of the laser diode 120. The second cylindrical portion 132 defines a second chamber 136 (See FIG. 7) to receive the collimated optics 122. The second cylindrical portion 132 includes a threaded portion 138 having external threads 140 to enable a threaded engagement of the housing 124, and hence the laser diode assembly 102, to the multi-pass cell (104, FIG. 1). The fins 170 may extend in a longitudinal direction and the fins 170 may be linearly arrayed in a lateral direction.

In one embodiment, the first chamber 134 and the second chamber 136 may be cylindrical chambers, and a diameter of the first chamber 134 may be greater than a diameter of the second chamber 136. Accordingly, a step 142 that extends inside the housing 124 is defined at an interface of the first chamber 134 and the second chamber 136. It may be appreciated that the laser diode 120 may abut the step 142 when arranged inside the first chamber 134. Further, the first cylindrical portion 126 may include a larger outer diameter relative to an outer diameter of the second cylindrical portion 132. To enable an insertion and removal of the laser diode 120 inside the first chamber 134, the first cylindrical portion 126 defines a first access opening 146 arranged at the first longitudinal end 128. The aforementioned principles may apply to any cavity receiving a laser diode.

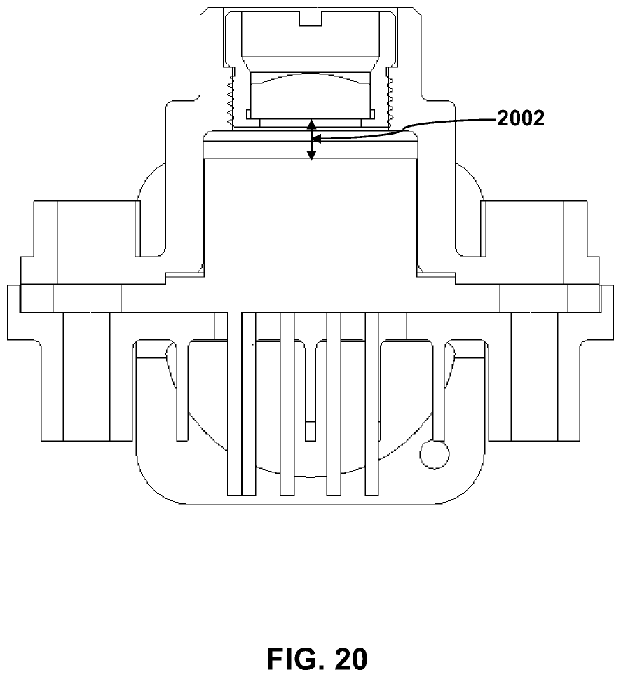

Similarly, the second cylindrical portion 132 defines a second access opening 150 of the second chamber 136 at the second longitudinal end 130 to enable an insertion and removal of the collimated optics 122 inside the second chamber 136. Collimated optics 122 may be inserted from either end. The collimated optics 122 may engage with the second cylindrical portion 132 via a plurality of screws (not shown) extending inside the second chamber 136 through a plurality of radial holes 152 and contacting the collimated optics 122. The radial holes 152 may be arranged proximate to the rstep 142 in some embodiments. The collimating optic distance from the emission source is shown in FIG. 20.

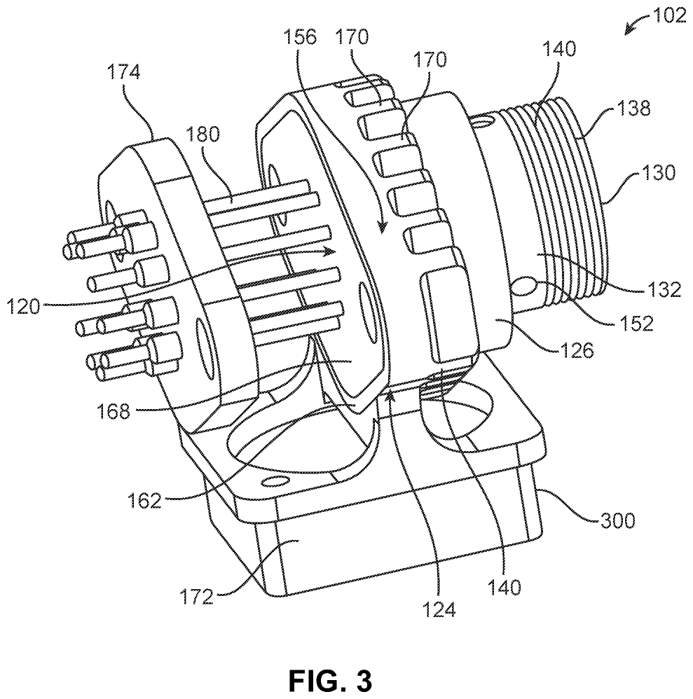

Additionally, the housing 124 may include a flange structure 156 extending radially outwardly from the first cylindrical portion 126 and connected to the first cylindrical portion 126. The flange structure 156 may facilitate an attachment of the laser diode 120 with the housing 124. The flange structure 156 may include a base 160 extending radially outwardly from the first cylindrical portion 126 and arranged at the first longitudinal end 128. In one embodiment, the base 160 may be a rhombus shape or a diamond shape. Other shapes are possible and contemplated. As shown, the flange structure 156 further includes a sidewall 162 extending along an entire outer edge 164 of the base 160 and disposed substantially perpendicularly to the base 160. The sidewall 162 extends in a direction away from the first cylindrical portion 126 and defines a cavity 166 to receive a mounting flange 168 (shown in FIGS. 3 to 5) of the laser diode 120. In an assembly, the mounting flange 168 is arranged inside the cavity 166 abutting the base 160. The sidewall 162 may be coupled to base 160 via a pair of fasteners (not shown). The mounting flange 168 may be made of a material that possesses a thermal conductivity of 10 Wm⁻¹K⁻¹ or higher at room temperature (e.g., graphene, aluminum, copper, gold, silver, steel, etc.) to better transfer heat generated by the laser diode 120.

Moreover, the flange structure 156 may include one or more heat transfer elements extruding from the flange structure 156. These heat transfer elements, or fins 170 may be attached to the base 160 and may extend outwardly towards the second longitudinal end 130 from the base 160. As shown, the fins 170 are arrayed linearly in a lateral direction and are arranged spaced apart from and substantially parallel each other. Other arrangements include fins that start at the center and extend radially outward, an array of cylinders, an array of prisms, or any arbitrary shape. The fins 170 facilitate in dissipating heat generated by the laser diode 120 and help maintain a temperature of the laser diode 120 within a desired range.

Further, the housing 124 may include a mounting bracket 172 connected to the flange structure 156 or to the first cylindrical portion 126 to enable a mounting of a fan 300 to the housing 124. The fan 300 may be adapted to provide a flow of air through the fins 170 to enhance heat dissipation or transfer from the fins 170 and hence the housing 124 to ambient. In one embodiment, the housing 124 and the fins 170 are made of a material having high heat conductivity and may be lightweight material that possesses a thermal conductivity of 10 Wm⁻¹K⁻¹ or higher at room temperature (e.g., graphene, aluminum, copper, gold, silver, steel, etc.), such as, aluminum. In some embodiments, the housing 124 further comprises a mounting bracket 172 configured to receive a secondary stage thermoelectric cooler (TEC) and heatsink assembly.

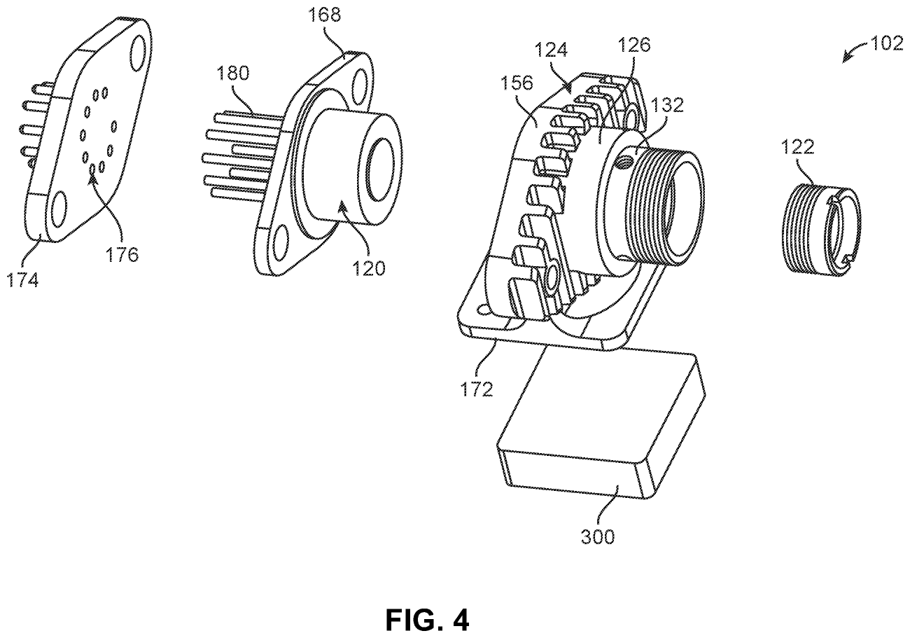

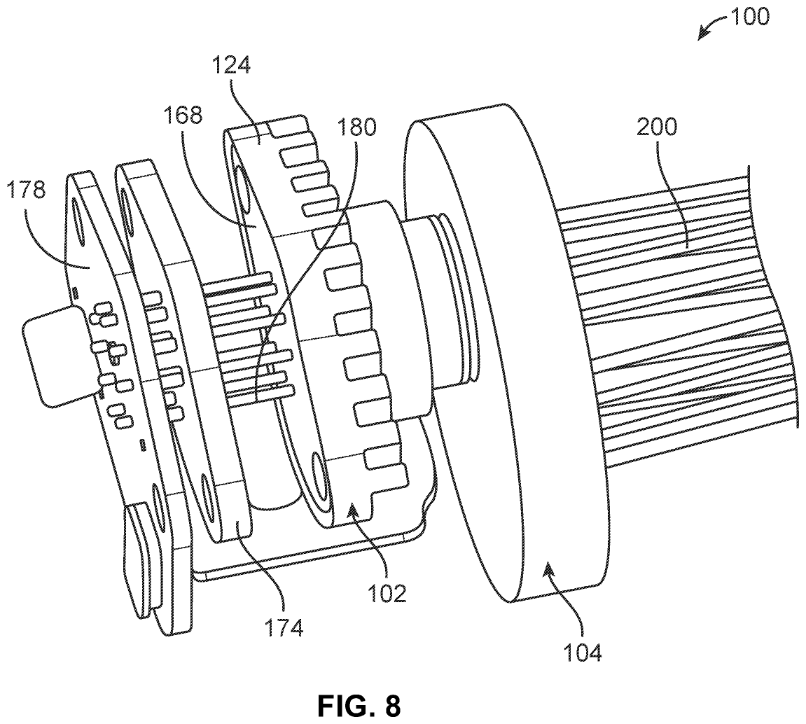

The laser diode assembly 102 may include a support flange 174 having a plurality of holes 176 (See FIG. 4) and a circuit board 178 (See FIG. 8) operatively coupled to the laser diode 120 via a plurality of pins 180. FIG. 8 depicts a portion of the laser assembly having a circuit board 178 operatively connected with a laser diode of the laser diode assembly 102, according to one embodiment. The pins 180 may extend from the mounting flange 168 to the circuit board 178 through the holes 176 (see FIG. 4) of the support flange 174. In other embodiments, the pins 180 may be connected to the circuit board 178. The heat generated by the laser diode 120 (as shown in FIG. 4) is released by first being transferred to the mounting flange 168.

The circuit board 178 ensures that the laser diode assembly 102 is being adequately cooled. In some embodiments, the circuit board 178 may include a microprocessor and a temperature sensor. In one embodiment, the laser diode assembly 102 can further include a thermoelectric cooler (TEC) and an external power source electrically connected to the thermoelectric cooler. The thermoelectric cooler acts as a heat pump and transfers the heat generated by the laser diode 120 to the flange 168. Conversely, the thermoelectric cooler may act as a heat pump to transfer heat.

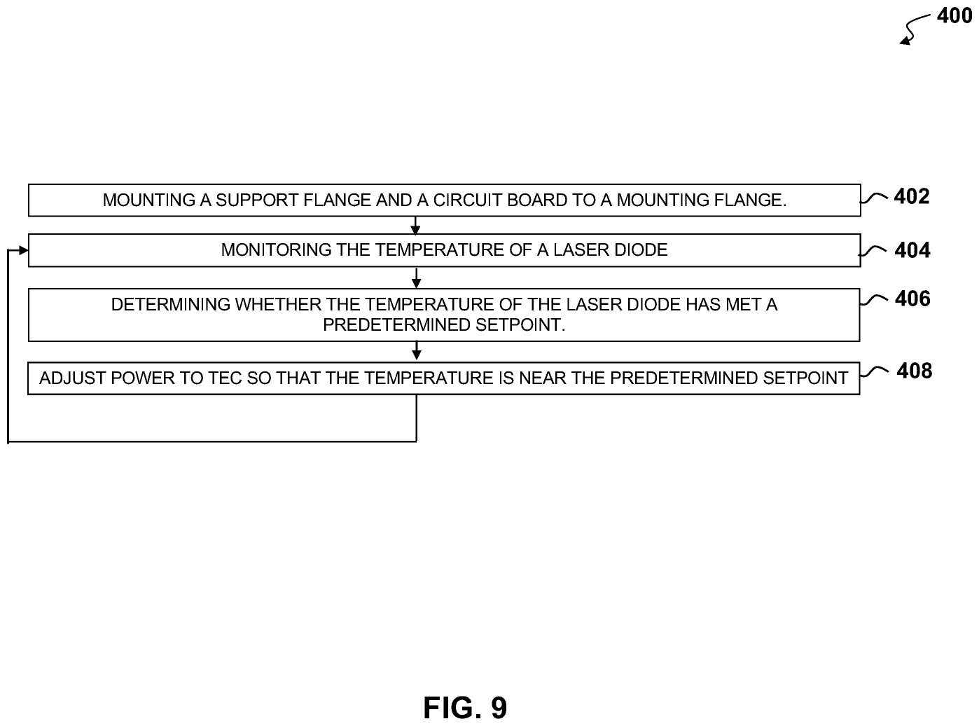

FIG. 9 is a flow chart of a method 400 for cooling a laser diode. The method 400 may include mounting a support flange and a circuit board to a mounting flange of a laser diode (step 402). The method 400 may then include monitoring a temperature of a laser diode (step 404). The method 400 may then include determining whether the temperature of the laser diode has met a predetermined setpoint (step 406). The method 400 may then include cooling or heating the laser diode so that the temperature of the laser diode is near the predetermined setpoint (step 408). After adjusting power to the TEC (step 408), method 400 repeats step 404 to form a feedback loop. The fan may additionally be modulated to increase or decrease the fan speed as necessary, in some cases turning the fan completely off. If the laser temperature cannot be maintained, a signal may be sent to the main microcontroller to turn off the laser. An objective is to control the temperature of the laser diode to within 0.1° C. of the desired setpoint.

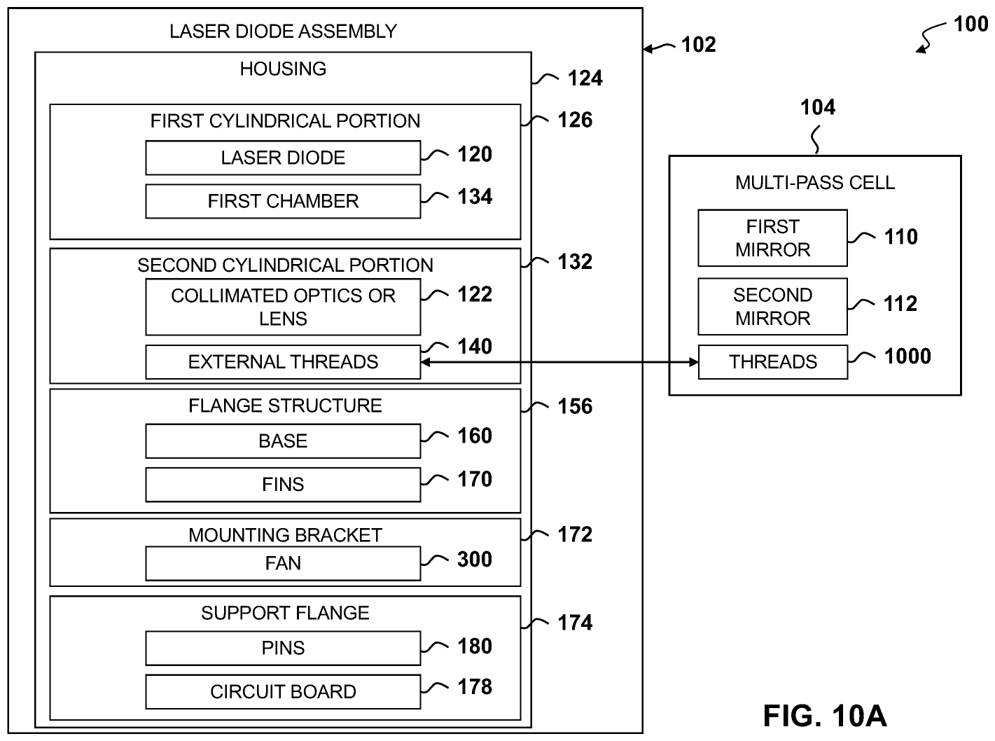

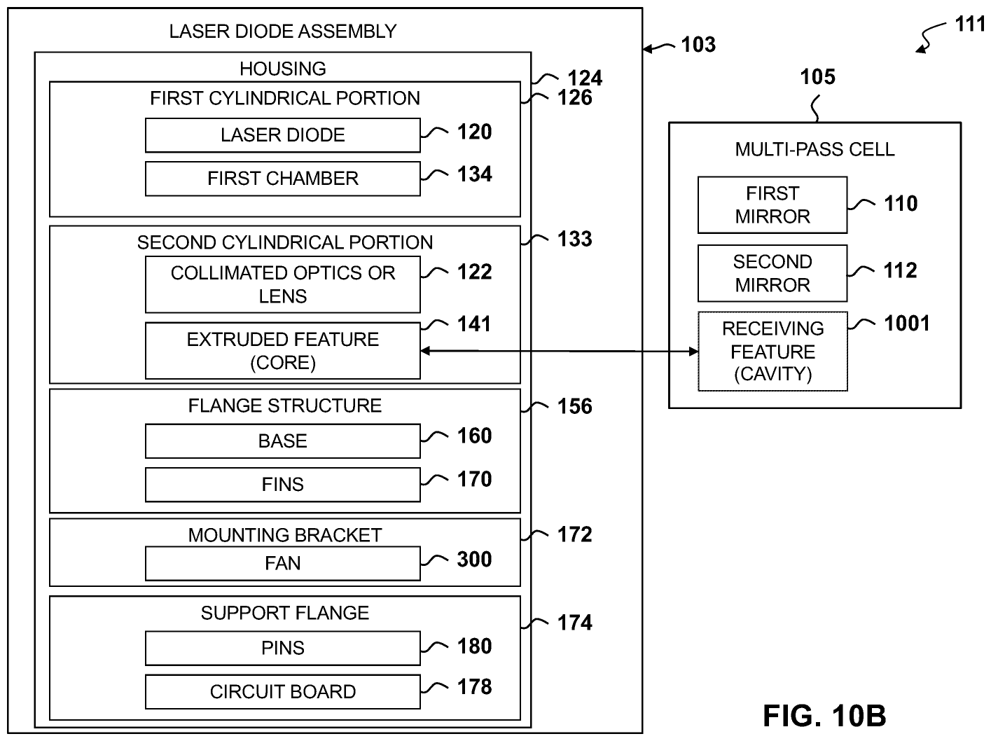

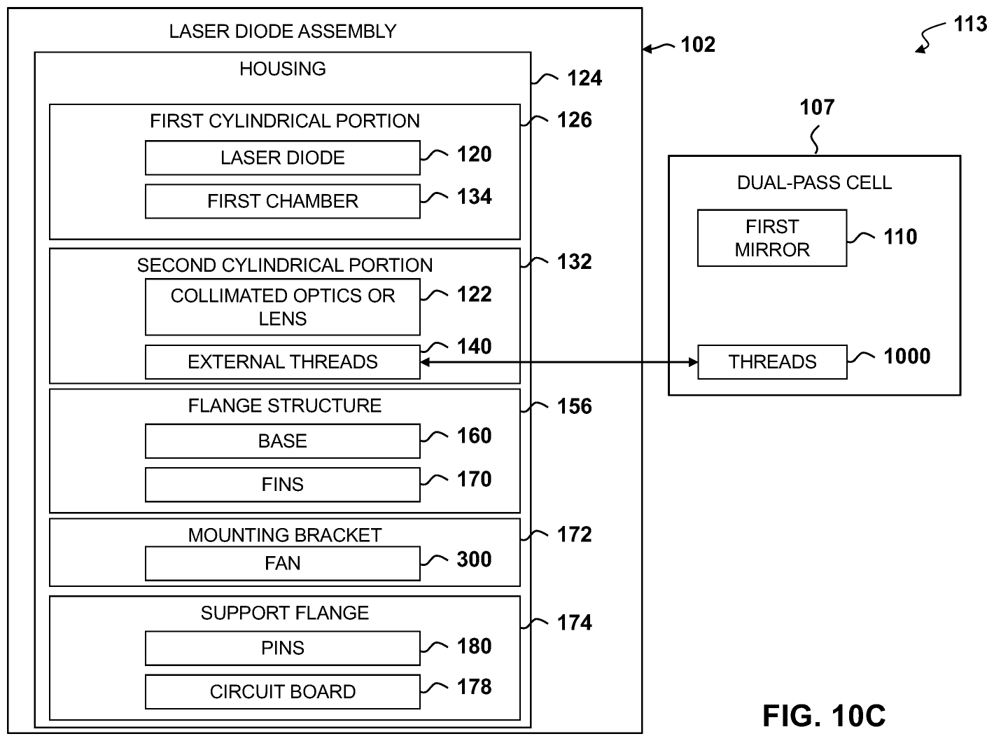

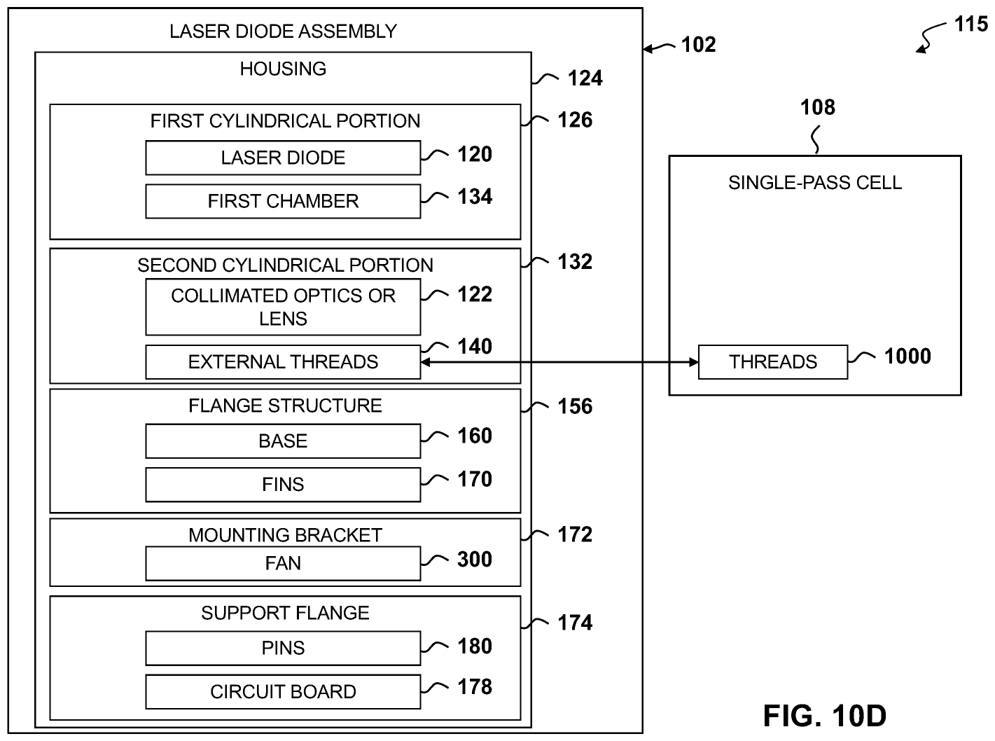

FIG. 10A is a high-level block diagram of a laser diode assembly 102 and multi-pass cell 104 of a laser assembly 100, according to an embodiment of the disclosure. The laser diode assembly 102 may include a housing 124. The housing 124 may include a first cylindrical portion 126, a second cylindrical portion 132, a flange structure 156, a mounting bracket 172, and a support flange 174. The first cylindrical portion 126 may include a first chamber 134 for receiving a laser diode 120. The second cylindrical portion 132 may include a collimated optics or lens 122 and external threads 140 for connecting to threads 1000 of a multi-pass cell 104. In one embodiment, the threads 1000 may be internal threads. The multi-pass cell 104 may include one or more mirrors, such as a first mirror 110 and a second mirror 112. The threads 140, 1000 may be used to connect the laser diode assembly 102 to the multi-pass cell 104.

The housing 124 may also include a flange structure 156. The flange structure 156 may include a base 160 and fins 170 for dispersing heat from the laser diode 120. The housing 124 may also include a mounting bracket 172 for the attachment of a fan 300. The fan 300 may provide further cooling of the laser diode assembly 102 by providing airflow over the fins 170. The housing 124 may also include a support flange 174. The support flange 174 may include a circuit board 178. The support flange 174 and circuit board 178 may be connected to the housing via one or more pins 180.

As previously described herein, a multi-pass cell 104 may direct the emission of a laser beam. For example, as stated, relative to FIG. 1, the laser beam 200 may enter inside the multi-pass cell 104 through an opening in the first mirror 110, reflect multiple time inside the multi-pass cell 104 between the first mirror 110 and the second mirror 112 over a path length, and exit the multi-pass cell 104 through an opening in the second mirror 112. Hence, laser beam 200 passes through multi-pass cell 104. As will be subsequently described herein, FIGS. 10B, 10C, and 10D illustrate other embodiments where a “pass-cell” or “multi-pass cell” may direct the emission of a laser beam, and different pass-cell configurations may have a difference number of mirrors.

FIG. 10B is a high-level block diagram of a laser diode assembly 103 and multi-pass cell 105 of a laser assembly 111, according to another embodiment of the disclosure. The pass-cell for this embodiment is multi-pass cell 105. The laser assembly 111 has similar features as laser assembly 100 except for elements in the second cylindrical portion 133 and multi-pass cell 105. Within second cylindrical portion 133, external thread (FIG. 10A, 140) has been replaced with extruded features (core) 141. In the multi-pass cell 105, the threads 1000 are provided by a receiving feature (cavity) 1001. Per FIG. 10B, extruded features (core) 141 may be coupled to the receiving feature (cavity) 1001 providing the entrance and exit path for a laser beam (FIG. 1, 200). The multi-pass cell 105 comprises two mirrors, first mirror 110 and second mirror 112.

FIG. 10C is a high-level block diagram of a laser diode assembly 102 and dual-pass cell 107 of a laser assembly 113, according to another embodiment of the disclosure. The laser assembly 113 has similar features as laser assembly 100 except for elements in the dual-pass cell 107. The pass-cell for this embodiment is a dual-pass cell 107. FIG. 10C illustrates using a dual-pass cell 107, wherein a dual-pass cell 107 contains only one mirror. Specifically, the dual-pass cell 107 comprises a first mirror 110 and threads 1000.

FIG. 10D is a high-level block diagram of a laser diode assembly 102 and single-pass cell 108 of a laser assembly 115, according to another embodiment of the disclosure. The laser assembly 115 has similar features as laser assembly 100 except for elements in the single-pass cell 108. The pass-cell for this embodiment is a single-pass cell 108. FIG. 10D illustrates using a single-pass cell 108, wherein a single-pass cell does not contain any mirrors. Specifically, the single-pass cell 108 only comprises threads 1000.

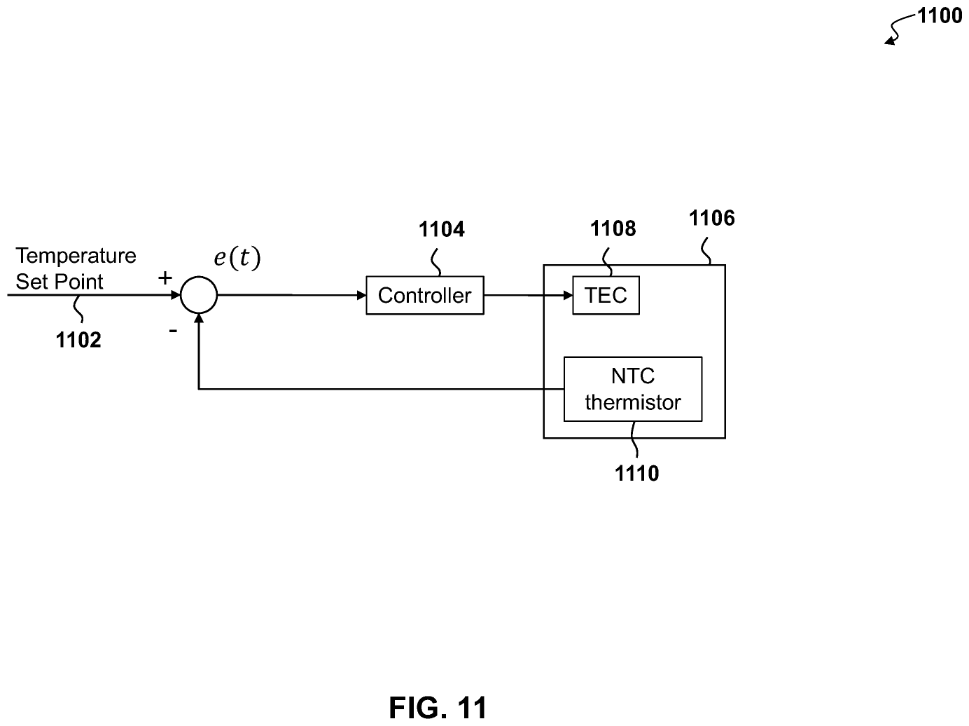

FIG. 11 is a temperature control block diagram 1100 using a controller, with a single stage, according to one embodiment. The temperature setpoint 1102 is provided to the TEC controller 1104. The TEC controller 1104 sends power to the TEC 1108 to change the temperature. A Negative Temperature Coefficient (NTC) thermistor 1110 is utilized to measure the temperature at the laser diode; then this value is fed back into the control loop and the error as a function of time (e(t)=T_setpoint−T_actual) is calculated. This error is used by the TEC controller 1104 to determine how much power to apply to the TEC 1108 to reach the temperature setpoint 1102. The disclosed method may be used to minimize errors. Power to the TEC 1108 is adjusted such that a monitored temperature of the laser diode 120 is near a predetermined setpoint. In other words, the temperature controller (1100) determines a difference between a setpoint temperature and an actual temperature. The TEC 1108 and NTC thermistor 1110 are co-located in block 1106.

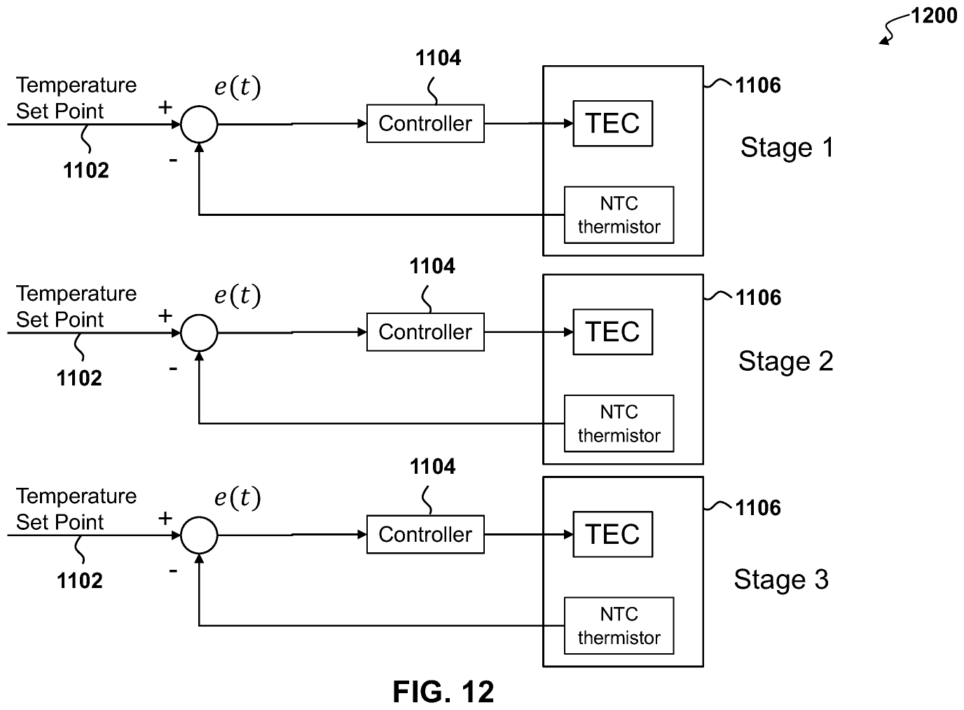

FIG. 12 is a temperature control block diagram 1200 using a processor, with three stages, according to another embodiment. The three stages, stage 1, stage 2 and stage 3 each comprise the same elements and connectivity as described for the temperature control block diagram 1100 in FIG. 11. The three stages provide for flexibility and accuracy in error calculations.

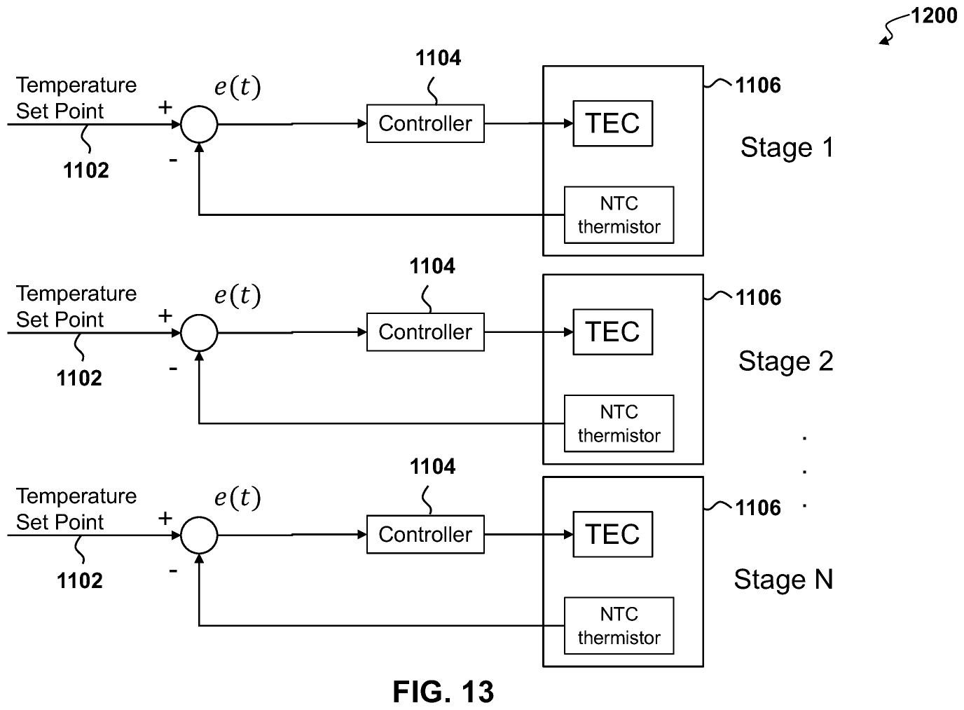

FIG. 13 is a temperature control block diagram 1300 using any computer, with N stages, according to another embodiment. Each of the stages, stage 1, stage 2 . . . , stage N comprise the same elements and connectivity as described for the temperature control block diagram 1100 in FIG. 11. The N stages provide for flexibility and accuracy in error calculations.

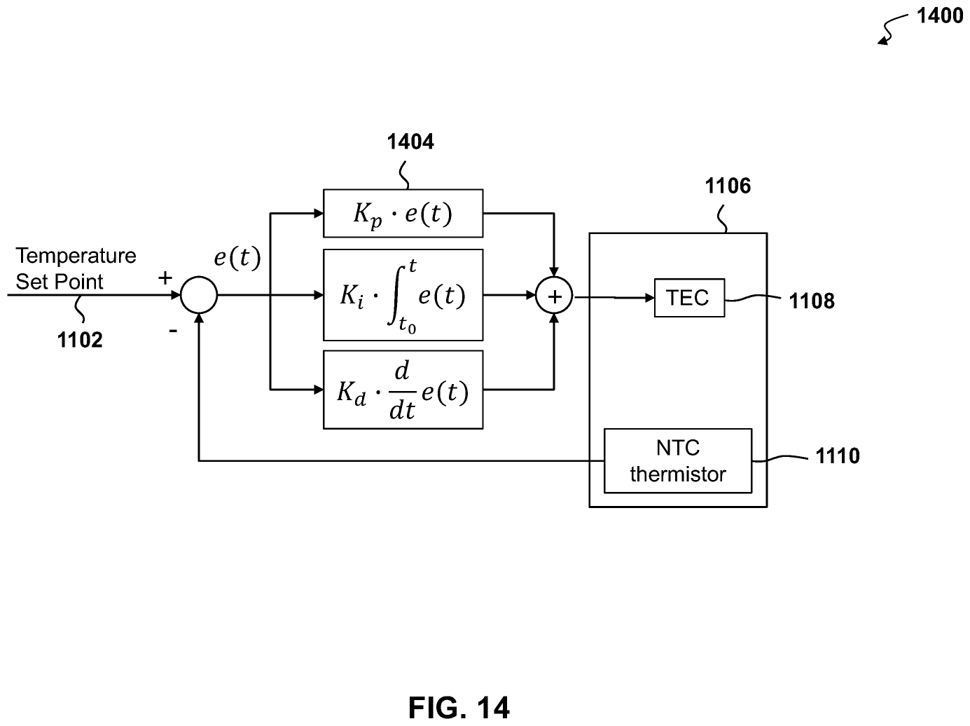

FIG. 14 is a temperature control block diagram 1400 using a PID loop, according to one embodiment. This configuration of the controller 1404 uses a proportional, integral, derivative (PID) loop to control the temperature. The gains (Kₚ, Kᵢ, and K_{d}) are constants that are set prior to applying the control loop, e(t) as calculated per FIG. 11, the integral is calculated over the entire time period of the controller in operation, and the derivative is calculated as the change from the previous time step to the current time step. The other elements in the temperature control block diagram 1400, are the same as discussed in FIG. 11, i.e., the temperature set point 1102, and the block 1106, which comprises the TEC 1108 and the NTC thermistor 1110.

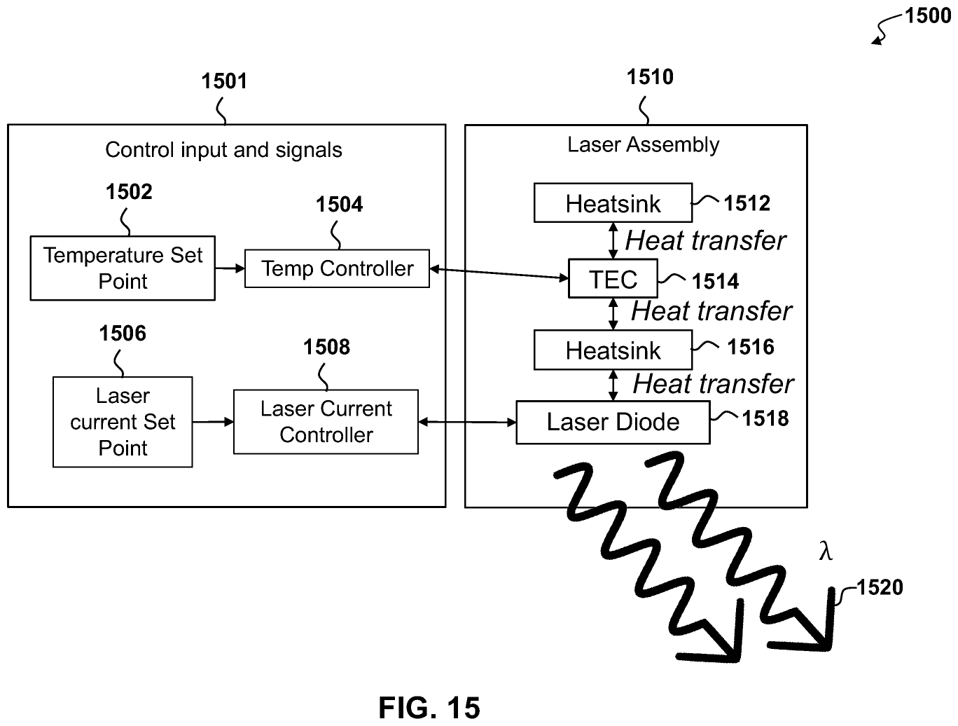

FIG. 15 is a tunable diode laser control 1500, according to one embodiment. The laser assembly 1510 comprises a heat sink 1512, a TEC 1514, a second heat sink 1516 and a laser diode 1518. The symbol λ is the wavelength of light 1520 determined by the material properties of the laser diode 1518 and controlled by the temperature of the laser diode 1518 and the current applied across the diode. The laser control may include one or more control input and signals 1501. The laser temperature setpoint 1502 is fed into the temperature controller 1504 and the temperature controller 1504 monitors the temperature of the laser diode 1518 and applies positive or negative current to the TEC 1514 to maintain the temperature setpoint 1502. The laser current (electrical current) from the laser current set point 1506 is fed into the laser current controller 1508, the laser current controller 1508 feeds a current into the laser diode 1518, allowing the forward voltage of the diode to be driven by the commanded current to the laser diode 1518. Accordingly, the laser diode 1518 generates a light wave 1520 with wavelength λ.

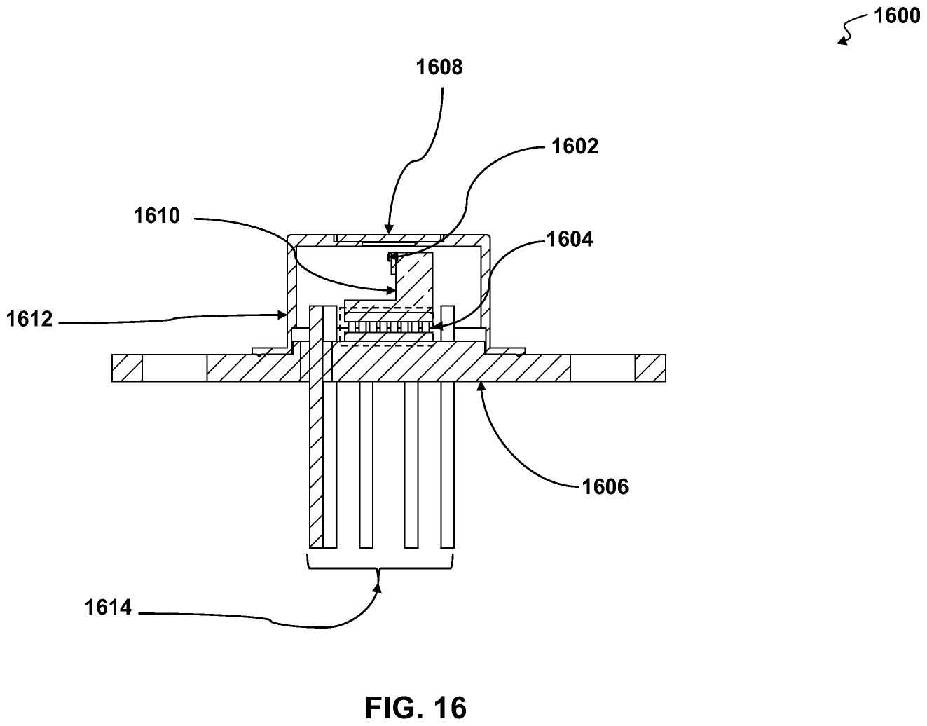

FIG. 16 is a laser diode assembly 1600 with an integrated Peltier Thermoelectric Cooler 1604, according to one embodiment. The laser diode assembly 1600 further comprises an emission source (diode) 1602, a Peltier thermoelectric cooler 1604, a heat sink 1606, a transparent window 1608, a diode mount, NTC thermistor, and a diode mount, NTC thermistor, and heat sink 1610, a cap 1612, and control and sense pins 1614.

In some embodiments, thermoelectric coolers can operate according to the Peltier effect. The Peltier effect can create a temperature difference by transferring heat between two electrical junctions. A voltage can be applied across joined conductors to create an electric current. When the current flows through the junctions of the two conductors, heat can be removed at one junction and cooling occurs. Heat may also be deposited at the other junction. In some embodiments, the application of the Peltier effect is cooling. However, the Peltier effect can also be used for heating or the control of temperature. Generally, a DC voltage is required.

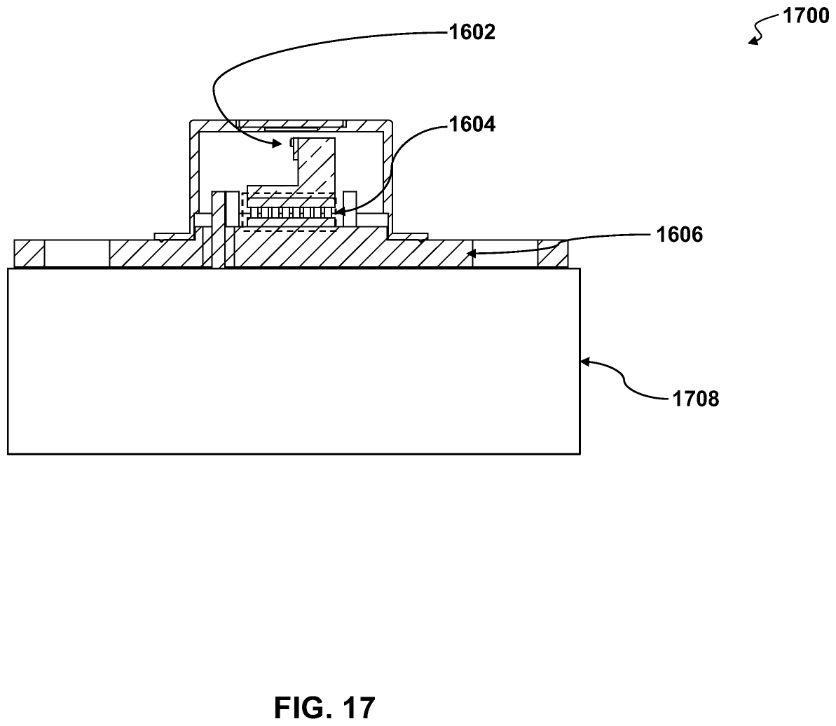

FIGS. 17-19 illustrate staging of heat sinks in a laser diode assembly with integrated Peltier Thermoelectric Coolers, according to some embodiments. FIG. 17 is a laser diode assembly 1700 with an integrated Peltier Thermoelectric Cooler 1604 (as shown by dashed lines), according to one embodiment. The laser diode assembly 1700 also comprises an emission source 1602 (diode), a heat sink 1606, and a secondary heat sink with fins 1708.

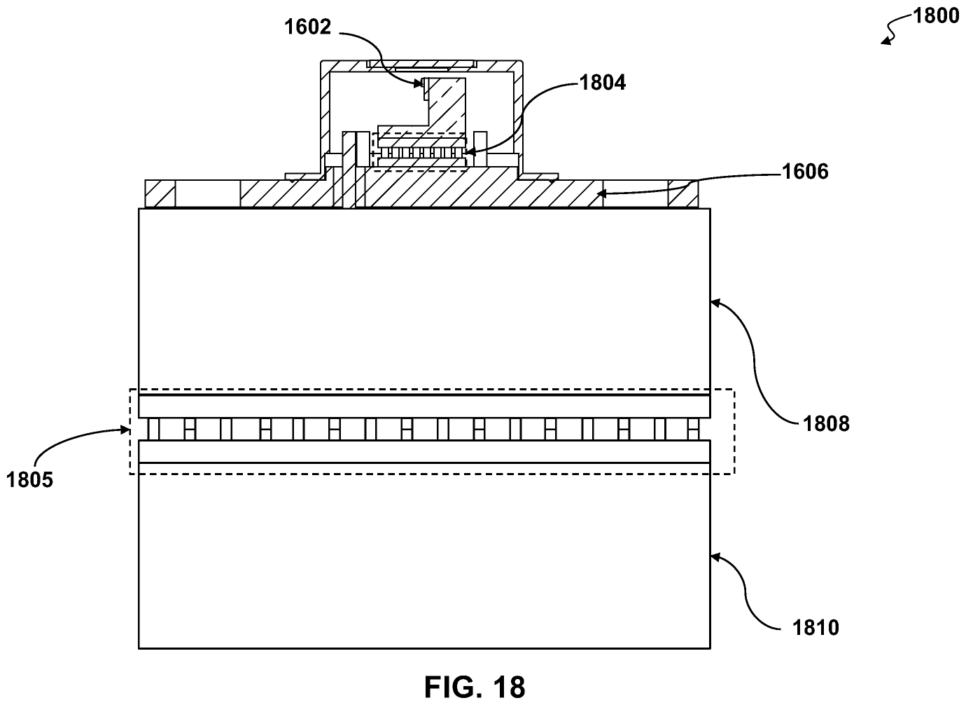

FIG. 18 is a laser diode assembly 1800 with an integrated first stage Peltier Thermoelectric Cooler 1804 (shown in dashed lines), according to another embodiment. The laser diode assembly 1800 also comprises an emission source 1602, a heat sink 1606, a second stage Peltier thermoelectric cooler 1805 (shown in dashed lines), a secondary heatsink with fins and a second NTC thermistor measuring this temperature 1808, where a second NTC thermistor measuring the temperature, and a tertiary heat sink with fins 1810. As shown in FIG. 18, a laser diode assembly 1800 comprises a stack of heat sinks including a heat sink 1606, a secondary heatsink with fins 1808, and a tertiary heat sink with fins 1810. FIG. 18 illustrates a physical separation between the secondary heatsink with fins 1808 and second stage Peltier thermoelectric cooler 1805.

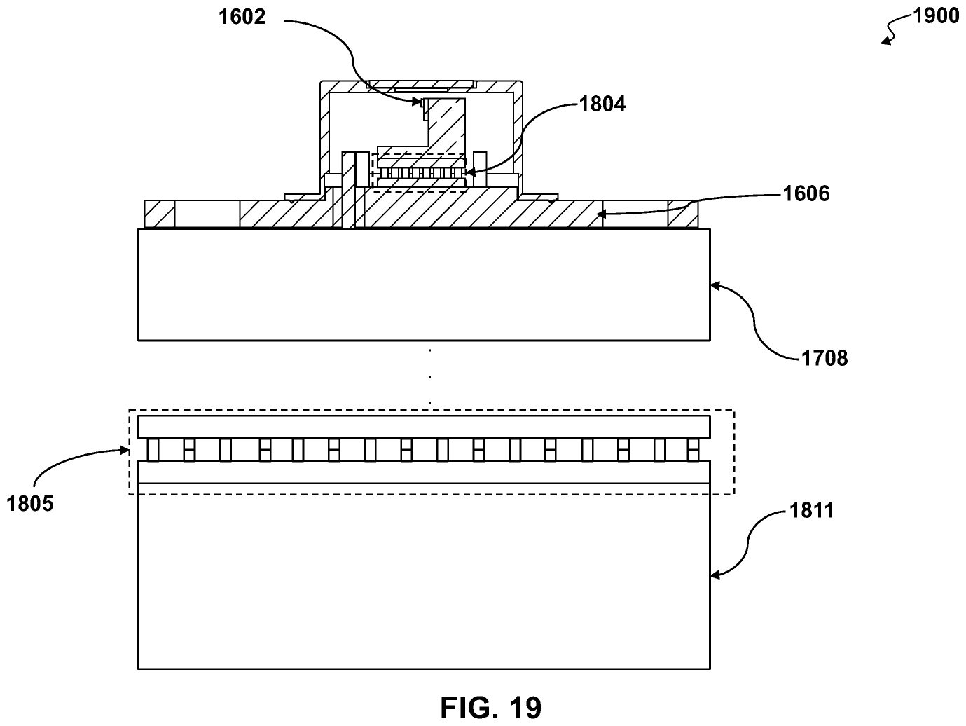

FIG. 19 is a laser diode assembly 1900 with an integrated first stage Peltier Thermoelectric Cooler 1804, according to another embodiment. The laser diode assembly 1900 also comprises an emission source 1602, a heat sink 1606, a Nth stage Peltier thermoelectric cooler 1805, a secondary heatsink with fins 1708, and a Nth heat sink with fins 1811.

FIG. 20 depicts a collimating optic distance 2002 from an emission source, according to one embodiment.

It is contemplated that various combinations and/or sub-combinations of the specific features and aspects of the above embodiments may be made and still fall within the scope of the invention. Accordingly, it should be understood that various features and aspects of the disclosed embodiments may be combined with or substituted for one another in order to form varying modes of the disclosed invention. Further, it is intended that the scope of the present invention herein disclosed by way of examples should not be limited by the particular disclosed embodiments described above.

1. A system comprising:
a laser diode assembly comprising:
a laser diode configured to emit a laser beam; and
a housing configured to receive at least a portion of the laser diode, wherein the housing comprises:
a first cylindrical portion defining a first chamber, wherein the laser diode is at least partially disposed in the first chamber; and
a flange structure connected to the first cylindrical portion, wherein the flange structure comprises a base extending radially outwardly from the first cylindrical portion and a plurality of fins arranged linearly along the base and extending outwardly from the base, wherein the plurality of fins facilitates in dissipating a heat generated by the laser diode, wherein a second cylindrical portion is configured to receive a collimated optics.

2. The system of claim 1, wherein the fins extend in a longitudinal direction and the fins are linearly arrayed in a lateral direction, wherein the laser diode is coupled to collimated optics, and wherein the collimated optics is coupled to a multi-pass cell.

3. (canceled)

4. The system of claim 1, wherein the housing further comprises a mounting bracket configured to at least one of: receive a fan and receive a secondary stage thermoelectric cooler (TEC) and heatsink assembly.

5. (canceled)

6. The system of claim 1, wherein the housing is mounted on a multi-pass cell, wherein the multi-pass cell comprises one or more mirrors, wherein the one or more mirrors of the multi-pass cell comprise a first mirror and a second mirror, wherein the first mirror is arranged spaced apart and opposite from the second mirror, wherein the first mirror is located at a predetermined distance from the second mirror, and wherein the laser diode assembly is coupled to the multi-pass cell proximate the first mirror.

7-8. (canceled)

9. The system of claim 1, further comprising:
a thermoelectric cooler (TEC) with an external power source electrically connected to the TEC, wherein power to the TEC is adjusted such that a monitored temperature of the laser diode is near a predetermined setpoint; and
a temperature controller that comprises a controller, the TEC, and a NTC thermistor coupled together in a control loop, wherein the temperature controller determines a difference between a setpoint temperature and an actual temperature.

10. (canceled)

11. The system of claim 1, further comprising:
a multi-pass cell configured to adapt and emit the laser beam;
wherein the laser diode assembly is mounted on the multi-pass cell.

12. The system of claim 11, wherein the second cylindrical portion comprises the collimated optics.

13. The system of claim 11, wherein the multi-pass cell is a multi-pass cell comprising a first mirror, a second mirror and threads, wherein the laser beam enters inside the multi-pass cell through an opening in the first mirror, reflects one or more times inside the multi-pass cell between the first mirror and the second mirror over a pass length, and exits the multi-pass cell through an opening in the second mirror, and wherein the collimated optics is coupled to the multi-pass cell via external threads and threads.

14-15. (canceled)

16. The system of claim 11, wherein the multi-pass cell is a multi-pass cell comprising a first mirror, a second mirror, and a receiving feature, and wherein the collimated optics is coupled to the multi-pass cell via extruded feature and receiving feature.

17. (canceled)

18. The system of claim 11, wherein the multi-pass cell is at least one of: a dual-pass cell comprising one mirror and threads and a single pass cell and does not comprise any mirrors.

19. (canceled)

20. The system of claim 1, wherein the first chamber comprises: a first end, a second end opposite to the first end, and an outer wall of the first cylindrical portion extending from the first end to the second end.

21. The system of claim 20, wherein the laser beam is configured to emit toward the second end from the first end.

22. The system of claim 20, wherein the second cylindrical portion is configured to connect onto the second end of the first cylindrical portion.

23. The system of claim 20, wherein the flange structure is configured to connect to the outer wall of the first cylindrical portion, wherein the base extends radially outwardly from the outer wall of the first cylindrical portion in a symmetrical shape with respect to a center of the first cylindrical portion, wherein the plurality of fins are arranged linearly along the base and extend outwardly from the second surface of the base toward an emitting direction of the laser beam, and wherein each fins of the plurality of fins contacts the outer wall of the first cylindrical portion.

24-25. (canceled)

26. The system of claim 1, wherein the flange structure further comprises a sidewall extending along an entire outer edge of the base, wherein the sidewall is disposed substantially perpendicularly to the base, and wherein the sidewall extends in a direction away from the first cylindrical portion.

27. A method for cooling a laser diode comprising:
monitoring a temperature of a laser diode;
determining whether the monitored temperature of the laser diode has met a predetermined setpoint; and
adjusting power to a thermoelectric cooler (TEC) such that a monitored temperature of the laser diode is near the predetermined setpoint.

28. The method of claim 27, further comprising:
mounting a support flange and a circuit board to a mounting flange of the laser diode.

29. The method of claim 27, further comprising:
mounting a laser diode assembly on a multi-pass cell;
wherein the multi-pass cell is configured to adapt and emit the laser beam;
wherein the laser diode assembly comprises:
a laser diode configured to emit a laser beam; and
a housing configured to receive at least a portion of the laser diode, wherein the housing comprises:
a first cylindrical portion defining a first chamber, wherein the laser diode is at least partially disposed in the first chamber; and
a flange structure connected to the first cylindrical portion, wherein the flange structure comprises a base extending radially outwardly from the first cylindrical portion and a plurality of fins arranged linearly along the base and extending outwardly from the base, wherein the plurality of fins facilitates in dissipating a heat generated by the laser diode, wherein a second cylindrical portion is configured to receive a collimated optics.

30. The method of claim 29, further comprising:
emitting the laser beam toward a second end from a first end;
wherein the first chamber comprises: the first end, the second end opposite to the first end, and an outer wall of the first cylindrical portion extending from the first end to the second end.

31. The method of claim 29, wherein the flange structure further comprises a sidewall extending along an entire outer edge of the base, wherein the sidewall is disposed substantially perpendicularly to the base, and wherein the sidewall extends in a direction away from the first cylindrical portion.
